(19) United States
(12) Patent Application Publication
(10) Pub. No.: US 2020/0403383 A1
(43) Pub. Date: Dec. 24, 2020

(54) SEMICONDUCTOR AMPLIFIER WITH LOW POLARIATION-DEPENDENT GAIN

(71) Applicant: NEC Laboratories America, Inc., Princeton, NJ (US)

(72) Inventors: Fatih YAMAN, Princeton, NJ (US); Shinsuke FUJISAWA, Princeton, NJ (US); Eduardo Mateo RODRIGUEZ, Tokyo (JP); Kohei NAKAMURA, Tokyo (JP); Takanori INOUE, Tokyo (JP); Yoshihisa INADA, Tokyo (JP); Takaaki OGATA, Tokyo (JP)

(73) Assignee: NEC LABORATORIES AMERICA, INC, Princeton, NJ (US)

(21) Appl. No.: 16/904,491

(22) Filed: Jun. 17, 2020

Related U.S. Application Data
(60) Provisional application No. 62/863,473, filed on Jun. 19, 2019.

(51) Int. Cl. H01S 5/50; H01S 5/00; H01S 3/10

(52) U.S. Cl. CPC H01S 5/5018; H01S 3/10061; H01S 5/0064

(57) ABSTRACT

Aspects of the present disclosure describe systems, methods and structures for providing semiconductor amplifiers exhibiting a low polarization-dependent gain.

### CROSS REFERENCE

This disclosure claims the benefit of U.S. Provisional Patent Application Ser. No. 62/863,473 filed Jun. 19, 2019, the entire contents incorporated by reference as if set forth at length herein.

### TECHNICAL FIELD

This disclosure relates generally to optical communications systems, methods, and structures. More particularly, it pertains to polarization dependent gain (PDG) of semiconductor optical amplifiers (SOA).

### BACKGROUND

As is known in the art, semiconductor optical amplifiers are a widely deployed component in contemporary optical communications systems—particularly undersea/submarine optical communications systems. A known infirmity of such SOAs however, is that they generally exhibit a large polarization dependent gain.

### SUMMARY

The above problem is solved and an advance in the art is made according to aspects of the present disclosure directed to SOA architectural arrangements/methods providing a reduction of the polarization dependent gain of SOAs.

In sharp contrast to the prior art, and viewed from a first aspect—systems, methods, and structures according to aspects of the present disclosure provide for the amplification of dual-polarization optical signals while overcoming polarization dependent gain problems that plague the art by directing the dual-polarization optical signals through a semiconductor optical amplifier at least twice—at least once in a first direction and at least once in a second direction wherein the second direction is opposite to the first direction. In this inventive manner, polarization dependencies are averaged out of the amplified signals.

### BRIEF DESCRIPTION OF THE DRAWING

A more complete understanding of the present disclosure may be realized by reference to the accompanying drawing in which:

FIG. 1 is a schematic diagram showing a prior art SOA arrangement in which each orthogonal polarization H and V are amplified by a separate single polarization SOA;

FIG. 2 is a schematic diagram showing an illustrative arrangement according to aspects of the present disclosure;

FIG. 3 is a plot showing illustrative simulation results for arrangement(s) according to aspects of the present disclosure;

FIG. 4 is a schematic diagram showing another illustrative arrangement according to aspects of the present disclosure; and

FIG. 5 is a schematic diagram showing an illustrative DP-SOA configuration operating in a single pass configuration according to aspects of the present disclosure.

The illustrative embodiments are described more fully by the Figures and detailed description. Embodiments according to this disclosure may, however, be embodied in various forms and are not limited to specific or illustrative embodiments described in the drawing and detailed description.

### DESCRIPTION

The following merely illustrates the principles of the disclosure. It will thus be appreciated that those skilled in the art will be able to devise various arrangements which, although not explicitly described or shown herein, embody the principles of the disclosure and are included within its spirit and scope.

Furthermore, all examples and conditional language recited herein are intended to be only for pedagogical purposes to aid the reader in understanding the principles of the disclosure and the concepts contributed by the inventor(s) to furthering the art and are to be construed as being without limitation to such specifically recited examples and conditions.

Moreover, all statements herein reciting principles, aspects, and embodiments of the disclosure, as well as specific examples thereof, are intended to encompass both structural and functional equivalents thereof. Additionally, it is intended that such equivalents include both currently known equivalents as well as equivalents developed in the future, i.e., any elements developed that perform the same function, regardless of structure.

Thus, for example, it will be appreciated by those skilled in the art that any block diagrams herein represent conceptual views of illustrative circuitry embodying the principles of the disclosure.

Unless otherwise explicitly specified herein, the FIGs comprising the drawing are not drawn to scale.

By way of some additional background, we note that submarine optical transmission systems—also known simply as submarine systems—have become a backbone of global communications. Nearly all data that travels between continents are delivered via these systems including optical cables laid on the floor of the seabed.

As will be readily understood and appreciated by those skilled in the art, there are several facets of a submarine (undersea) transmission (communications) system that sets it apart from other fiber communication systems, namely: 1) they include very long optical cables, and require repeaters; and 2) all electrical power must be supplied from end(s) of the cable as there are no under ocean power sources. Therefore, the amount of power that can be delivered to repeaters along the cable length is limited. Accordingly, it is especially important to make sure the amplifiers in the repeaters use as little power as possible. Finally, it is expensive to lay cables under water and once a cable is laid, it is extremely expensive to replace, upgrade, or repair the cables. Consequently, it is of course quite important to be able to transmit signals over submarine cables without degradation.

As noted, submarine cables are very long, and oftentimes span several hundred to several thousand kilometers. Since optical signal(s) attenuate as they traverse optical fiber comprising the submarine cable. Consequently—at lengths of only a few tens of kilometers, and typically less than a 100 km—the signal(s) need to be periodically amplified.

By convention, optical fiber residing between two optical amplifiers is generally known as a span. As an illustrative example, a trans-pacific cable that is 10000 km long with 80 km spans would include approximately 120 optical amplifiers. Since many optical amplifiers are cascaded in a long-distance transmission implementation, any imperfection imparted by individual amplifiers compounds to a huge degradation when contributed by tens or even hundreds of amplifiers. Accordingly, it is exceedingly important that optical amplifiers in such application have little imperfection. Therefore, it is extremely important to ensure the amplifiers have little imperfection.

As is known, optical amplifiers require electrical power to re-amplify optical signals. Since that electrical power that can be delivered to the amplifiers through the optical cable is limited, it is important to make sure the amplifiers are power efficient, which means providing gain with little electrical power consumption.

As noted previously, one known imperfection with respect to semiconductor optical amplifiers is that they sometimes exhibit PDG. Operationally, PDG indicates that one polarization of the signal receives more gain than the other polarization. Even though the orientation of the PDG may vary randomly, after many cascades of amplifiers with PDG, the signal-to-noise ratio (SNR) of a signal is degraded significantly, unless the PDG of each SOA is reduced to below approximately 0.2 dB. Unfortunately, however, it is very difficult to reduce the PDG of SOAs to a level below 1 dB.

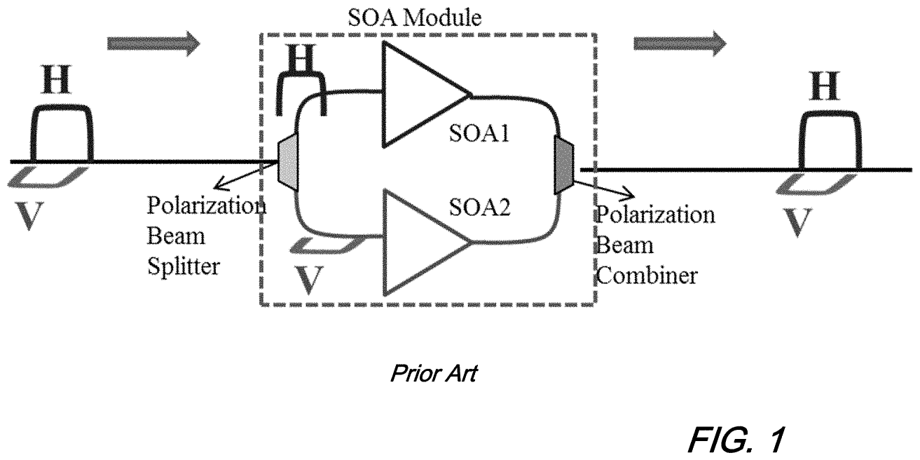

FIG. 1 is a schematic diagram showing a prior art SOA arrangement in which each orthogonal polarization H and V are amplified by a separate single polarization SOA.

As may be observed from that figure, at an input of an illustrative SOA module, a signal is separated into two orthogonal polarizations, H and V. Each individual polarization is then amplified by a separate single-polarization SOA. After amplification, the individual, separately amplified outputs are subsequently combined using a polarization combiner. Operationally, with such a prior art configuration, the gain(s) of each of the two SOAs are configured to be equal to one another, which, as those skilled in the are will appreciate, is relatively easy as each SOA only amplifies a single polarization.

Notwithstanding such ease of implementation, there exist several known disadvantages to such a prior art approach.

For SOAs, power consumption is directly related to signal gain and little relationship to signal output power. Since—in the case of the prior-art configuration shown in the figure—the SOA module includes two individual SOAs and each SOA provides the same gain, the power consumption is substantially doubled as compared to a single SOA amplifies both polarizations simultaneously. Note that this is true even though each SOA is amplifying only half of the signal (one polarization) since—as noted—power consumption has little relationship to output signal power. As mentioned previously—and as will be immediately appreciated—power efficiency is quite critical to submarine systems.

Additionally, with respect to the prior art configuration shown, any polarization beam splitter and polarization beam combiner used should exhibit an extremely high extinction, otherwise, an output signal will suffer from multi-path interference, and fading. As used herein, extinction in this context means how well the polarization beam splitter splits the two polarizations. For instance, if the extinction is 20 dB, on an H arm there will still be a V signal—at a 20 dB reduced level as compared to its value at input to the splitter.

Further, if the gain(s) of the two SOAs inside the SOA module are not prepared in identical fashion, the gains will need to be readjusted by setting/adjusting specific current value(s) to the individual SOAs. However, this leads to slight changes in the shape of the gain spectrum, which makes it difficult to achieve low PDG across the gain spectrum.

Finally, we note that prior-art configurations such as that shown in the figure is more costly as it requires at least two SOAs and occupies greater mass/volume due to the SOAs and other necessary elements including those to split/recombine signal(s).

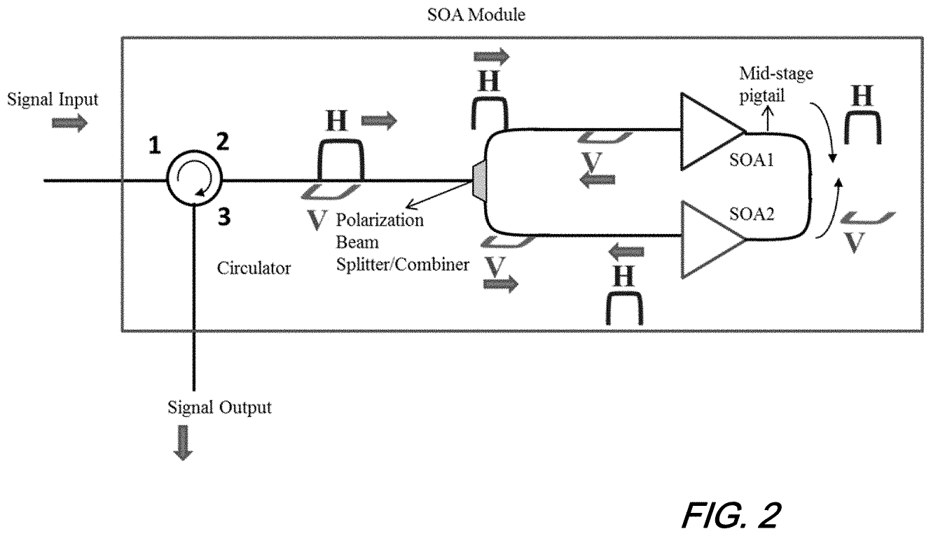

FIG. 2 is a schematic diagram showing an illustrative SOA module arrangement according to aspects of the present disclosure.

With reference to that figure, it may be observed that a dual-polarization signal is input to the SOA module wherein it is received at port 1 of a circulator. The circulator directs the received dual-polarization signal to circulator port 2.

From circulator port 2, the dual polarization signal is directed to polarization beam splitter/combiner and split into horizontal (H) and vertical (V) components through the effect of the polarization beam splitter/combiner. The (H) horizontal polarization is directed to an SOA (SOA1) via upper arm and amplified through the effect of SOA1, and (V) vertical polarization is directed to SOA (SOA2) via lower arm and amplified through the effect of SOA2.

After the two polarizations are individually amplified, they are directed to the other amplifier in the opposite direction. For example, the amplified (V) vertical polarization is directed to SOA1 and the amplified (H) horizontal polarization is directed to SOA2 in which they are each amplified once again.

Following this second amplification, each individual polarization is directed to, and re-enters the polarization beam splitter/combiner at an opposite port from which it previously exited. The two polarization components are re-combined together through the effect of the polarization beam splitter/combiner. This results in a signal exhibiting an amplified signal with combined polarization components (dual polarization). This re-combined dual polarization signal is directed to circulator port 2 which directs the signal to circulator port 3 from which it is output.

As may now be appreciated and understood, in the illustrative arrangement shown in the figure, each individual polarization is individually amplified by each of the two SOAs (chips), one SOA in a first direction and the other SOA in a second, opposite direction. Typically, the SOAs have similar gain in both directions, therefore, both polarizations will experience the sum of the gains of both SOA chips. As a result, polarization-dependent gain is eliminated. Note that, even though the gain of SOA1 and SOA2 may differ, both polarizations will experience the same total gain which is the sum of the gains of both polarizations.

We note that in certain optical communications systems, signals propagate in only one direction and such systems are oftentimes referred to as a unidirectional system. Inasmuch as our arrangement employs signals propagating in both directions—in some parts—it may be referred to as a bidirectional system.

We note that our configuration according to the present disclosure may advantageously be packaged in at least two different illustrative ways. First, a compact package, where both SOA chips are packaged together with polarization beam splitter. In this packaging configuration—that we named “mid-stage pigtail”—is very short, therefore any delay between a signal exiting one SOA and entering the other SOA is very small.

In a second illustrative packaging configuration, the two SOAs may be optically connected via a relatively long optical fiber or other optical interconnect such that an optical delay between SOA exit and SOA entrance results. We note that while a compact package may exhibit space advantages, having a relatively long, “mid-stage delay pig-tail”, may also provide performance benefits in regard to reducing nonlinear impairment.

To further illustrate advantages resulting from our configuration(s), we note that a circulator is a device that guides an optical signal entering circulator port 1 to circulator port 2, and an optical signal entering circulator port 2 to circulator port 3—while blocking any optical signals from entering circulator port 3.

Even though our configurations require the use of a circulator, this is not a disadvantage, because, when SOAs are used as inline amplifiers, isolators are necessarily positioned at both at the input and at the output of the amplifier module to avoid instabilities that may arise from any reflections. The circulator employed in our configurations replaces the use of two such isolators. Therefore, our configurations in total use less components, i.e., only one polarization beam splitter/combiner, and only a single circulator instead of two isolators. Note also that polarization beam splitters are linear, passive devices and by design they act as a splitter and combiner at the same time. As a result, our design configurations are advantageously both less expensive and more compact than prior art configurations.

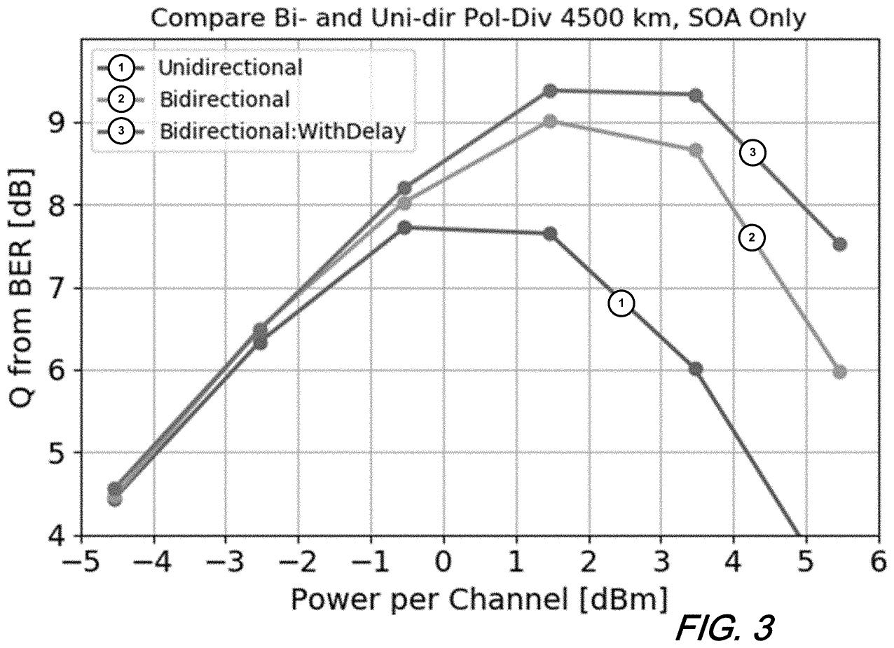

As we shall show and describe, yet another advantage of our configurations is less nonlinear penalty. FIG. 3 is a plot showing illustrative simulation results for configurations according to aspects of the present disclosure. As shown in that figure, it may be observed that configurations according to aspect of the present disclosure exhibit better nonlinear performance as compared to the prior art.

To further explain this surprising advantage, we note that configurations according to the present disclosure exhibit nonlinear impairment because, in our configurations—in each of the SOA chips—two independent polarization tributaries are traveling simultaneously. This causes an averaging effect, which is completely absent in a uni-directional design.

Those skilled in the art will appreciate that such averaging is important because—in SOAs—nonlinearity is caused by gain saturation. Gain saturation is needed to make an SOA more power efficient. Those skilled in the art will understand that gain saturation is defined as a condition that exists when signal power is increased, and an SOA cannot provide any additional gain or results in gain suppression. Therefore, even if we design an SOA to provide appropriate gain for an average signal power—because an optical signal carries data—its power fluctuates depending on the data pattern. Accordingly, for portions of an optical signal in which signal power is larger than average—due to a particular data pattern—gain will be reduced. When signal power reduces, gain will increase.

In an SOA, this fluctuation of gain is accompanied by phase fluctuations that is proportional to the gain fluctuations, and the proportionality factor is sometimes called a Henry parameter, or a linewidth broadening parameter. This pattern dependent stochastic variation of the phase imprinted on the signal is the source of the nonlinear penalty noted above. If we have two independent signal tributaries existing in the SOA at the same time—as is the case with configurations according to aspects of the present disclosure—the fluctuations of these signals add up incoherently and average. Therefore, systems and configurations according to aspects of the present disclosure advantageously exhibit substantially less nonlinearity that plagues the art.

In addition to the averaging described above, there is an additional averaging effect if the midstage pigtail described previously is long enough.

Consider a horizontal polarization tributary. Assume it enters SOA1 at a time, t0. At t0, the horizontal polarization tributary will average out with a vertical polarization also in SOA1. When the horizontal polarization enters SOA2, it will average with an advanced (advanced in time) version of the vertical polarization in SOA2. As a result, that horizontal polarization tributary actually averages with two different vertical polarization signals—once in SOA1 and once in SOA2—and therefore receives the additional averaging. Note however, that the magnitude of a vertical polarization in SOA1 and SOA2 are not the same, therefore the degree of averaging is less as compared to an averaging that would occur between 3 similar power signals. Nevertheless, it is greater averaging than would occur between 2 independent signals of similar magnitude. Note further that the length of the midstage pigtail depends on the time response characteristic of the SOAs.

Typically, SOAs cannot respond to changes that occur faster than their carrier lifetime. In some cases, when the SOA is operated in saturation, the response time will become shorter than the carrier lifetime. In any case, as long as the delay induced by the pigtail is longer than SOA carrier lifetime, any additional averaging will contribute. Longer delays will provide more averaging however, it will saturate after some point. To give examples, typically the carrier lifetime of SOAs vary between 100 ps and 1 ns. This means, the pigtail needs to induce a delay longer than 50-500 ps, because pigtail induces delay to both polarizations. If a glass fiber is used as pigtail, with refractive index of the order of 1.5, this means a pigtail of about 1 cm to 1 m in length.

We note that while we have used the term “pigtail” to describe the optical path between the two semiconductor optical amplifiers, our optical path/interconnect between the two amplifiers need not be optical fiber. In particular, any medium capable of conveying optical signals including waveguide implementations, or adjustable and/or variable delay(s) are contemplated as well as optical fiber of varying length(s).

Those skilled in the art will understand and appreciate that still another advantageous benefit of systems, methods, and structures according to aspects of the present disclosure is that they may reducing the impact(s) of fiber nonlinearity when SOAs are used as inline amplifiers. As is known, inline amplifiers are used for long distance transmission where a fiber is used to transmit the signal over a long distance, and amplifiers are used to compensate for the loss from the fiber. Fibers also impart nonlinearity to the signal and depending on the sign of the Henry parameter, nonlinearity of the fiber may add or subtract from the SOA nonlinearity. Typically, however, the sign of Henry parameter is such that they add.

In systems, methods, and structures according to aspects of the present disclosure, it is possible to adjust the delay between the polarization beam splitter and each of the SOAs so that the optical path (pigtail) from polarization beam splitter to SOA1 is longer than the optical path length (pigtail) to SOA2. In this case, the nonlinearity occurring in the optical fiber will result from a different pattern effect as compared to nonlinearity occurring in the SOAs—which advantageously reduces the combined nonlinearity contributed by the fiber and SOAs.

To emphasize why reducing nonlinear impairments are important we note the following. Nonlinear impairments reduce signal quality and reduce achievable capacity. But—in the case of SOAs—there is another benefit to such reduction. Generally, SOAs exhibit (suffer) low power efficiency, meaning they consume too much power to provide a sufficient gain. However, for SOAs it is generally possible to design same to reduce their saturation power, which improves their power efficiency. Unfortunately, if an SOA is so designed, the SOA becomes more nonlinear because even small signals would produce SOA saturation and be affected by nonlinearity. Accordingly, there exists a design tradeoff between SOA nonlinearity and power efficiency. Fortunately, and as will be readily appreciated by those skilled in the art, systems methods, and structures according to aspects of the present disclosure—which already exhibit superior nonlinear characteristics—can be made even more power efficient at the same capacity performance as that offered in the prior art.

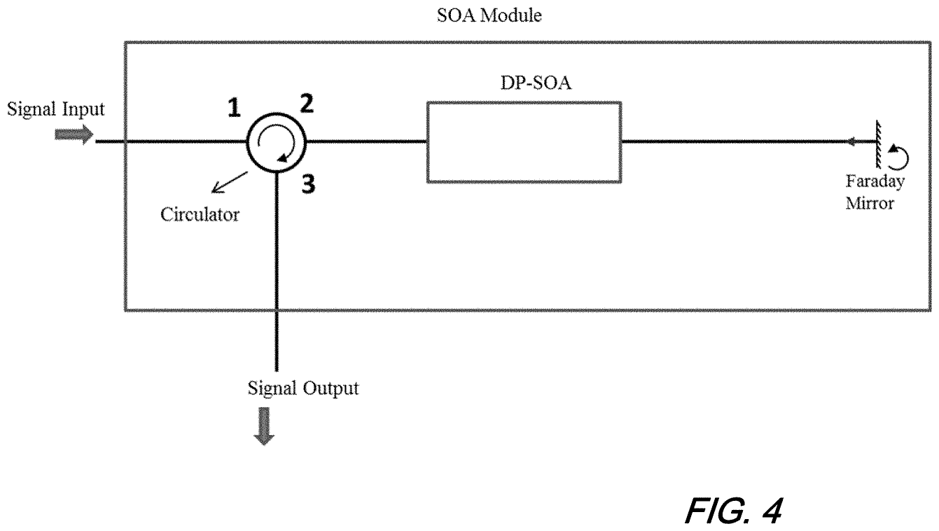

FIG. 4 is a schematic diagram showing another illustrative arrangement according to aspects of the present disclosure. Shown in that figure is an illustrative SOA module including a circulator, a dual-polarization SOA and a Faraday mirror optically interconnected.

Operationally, a dual-polarization optical signal enters the module via an input port and is shown received by port 1 of circulator, exiting the circulator via circulator port 2. The signal, upon exiting the circulator, is directed to dual-polarization SOA (DP-SOA). The amplified signal(s) exit the DP-SOA and are directed to a Faraday mirror (FM) via pigtail—or other optical path (i.e., waveguide)—where it is reflected back towards the DP-SOA. The reflected signal(s) are then amplified a second time through the effect of the DP-SOA and the 2×amplified signal(s) are directed to circulator where they enter circulator port 2 and are directed to circulator port 3 at which they exit the circulator and the module.

As will be appreciated by those skilled in the art, we may advantageously employ dual-polarization SOA chips in the module that may advantageously amplify both polarizations simultaneously. However, since such dual-polarization SOAs provide different gains for the different polarizations, they suffer from PDG.

Advantageously, however, according to aspects of the present disclosure, the Faraday mirror rotates reflected light by 90 degrees. As such, horizontally polarized light striking the FM will rotate 90 degrees and become vertically polarized, and vertically polarized light striking the FM will rotate 90 degrees and become horizontally polarized. Moreover, even if the fiber pigtail optically connecting the D-P SOA and FM is not polarization maintaining, as the signal(s) exit(s) the SOA and travel(s) through the pigtail to the FM, reflects, and returns to the SOA via the same pigtail, it will have the opposite polarization orientation as when it exited the SOA. Therefore, the polarization that had lower gain the first pass, will get the larger gain in the second pass in the opposite direction, and vice versa. As a result, both polarizations will experience the sum of the low and high gain, and therefore will result having with the same total gain.

Of further advantage, systems, methods, and structures according to aspects of the present disclosure eliminate PDG better than the prior art because there is no need for a careful balancing of gain between two SOA chips. In addition to having fewer components, systems, methods, and structures according to aspects of the present disclosure are more power efficient than exhibited by the prior art. This is due—in part—to the fact that an SOA gain determines required current. Since in prior art, two SOA chips—each generating same gain albeit for half signal power—are employed, they require roughly double the current than required by systems, methods, and structures according to aspects of the present disclosure. Additionally, systems, methods, and structures according to aspects of the present disclosure—(our design 2 (FMSOA)), reduces nonlinearity non only to the prior art but even as compared to an ideal DP-SOA that does not exhibit PDG. Note that by ideal DP-SOA, we mean an SOA that amplifies a dual polarization signal without PDG and is operated in a single-pass configuration.

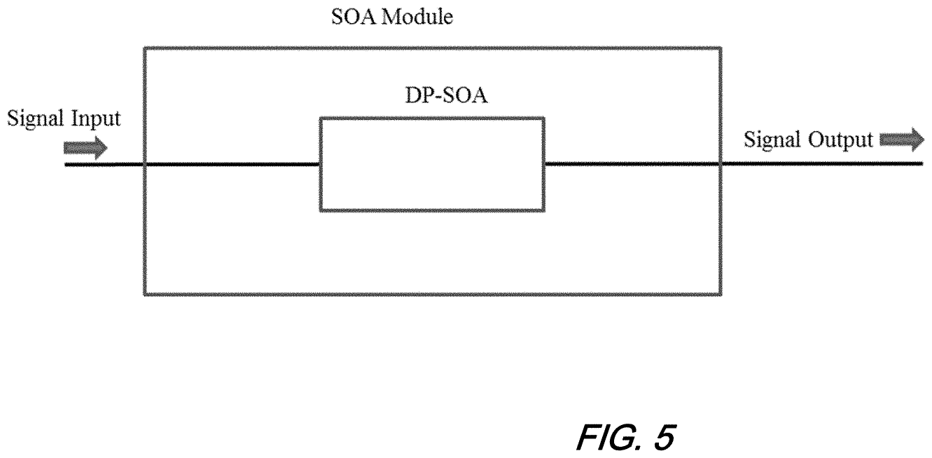

FIG. 5 is a schematic diagram showing an illustrative DP-SOA configuration operating in a single pass configuration according to aspects of the present disclosure. At this point we that in FMSOA configuration shown schematically in FIG. 4, there are four independent tributaries traveling at the same time namely, two polarization tributaries in the forward direction, and two polarization tributaries in the backward direction. Note that, even if it was possible to manufacture a DP-SOA that did not suffer from PDG, (this is very difficult and this is why the prior art as shown in FIG. 1 was designed), our FMSOA configuration would be more desirable because our FMSOA configuration would reduce nonlinearity as compared to an ideal DP-SOA, because FMSOA provides averaging over four independent tributaries, compared to only two in the case of the ideal DP-SOA.

Similar to our earlier presented configuration, this second configuration also exhibits a nonlinearity suppression if the pigtail between the SOA and the FM is sufficiently long. As before, the propagation time for optical signals (time of flight) from SOA exit to FM and back to SOA exit is sufficiently long when it is longer than the SOA carrier lifetime. In such case, the module exhibits an additional averaging benefit as tributaries not only overlap in forward and backward direction but they overlap between delayed versions of them as well.

While we have presented this disclosure using some specific examples, those skilled in the art will recognize that our teachings are not so limited. Accordingly, this disclosure should be only limited by the scope of the claims attached hereto.

1. A semiconductor optical amplifier module exhibiting low polarization dependent gain characteristics, said module comprising:
an input port for receiving a dual-polarization signal and an output port for outputting an amplified dual-polarization signal;
an optical circulator in optical communication with the input port, the output port, and a polarization beam splitter/combiner, said circulator configured to direct optical signals between the input port, the output port, and the polarization beam splitter/combiner; and
a pair of semiconductor optical amplifiers, each having a first port and a second port, the first port of each optically connected to the polarization beam splitter combiner, and the second port of each optically connected to one another.

2. The module of claim 1 configured such that an H polarization of the dual-polarization signal is amplified by one of the semiconductor optical amplifiers traversing that amplifier in a first direction and amplified by the other one of the semiconductor optical amplifiers traversing that other amplifier in an opposite direction.

3. The module of claim 2 configured such that an V polarization of the dual-polarization signal is amplified by one of the semiconductor optical amplifiers traversing that amplifier in a first direction and amplified by the other one of the semiconductor optical amplifiers traversing that other amplifier in an opposite direction.

4. The module of claim 1 further comprising:
an optical pigtail, connecting the second port of each optical amplifier to one another.

5. The module of claim 4 wherein the optical pigtail introduces a transmission delay in optical signals from one semiconductor optical amplifier to the other semiconductor optical amplifier, said transmission delay configured such that it is longer than a carrier lifetime of the semiconductor optical amplifiers.

6. An improved optical amplifier module exhibiting low polarization dependent gain comprising:
an input port for receiving a dual-polarization signal and an output port for outputting an amplified dual-polarization signal;
an optical circulator in optical communication with the input port, the output port, and a dual-polarization semiconductor optical amplifier, said circulator configured to direct optical signals between the input port, the output port, and the dual-polarization semiconductor optical amplifier;
the dual-polarization semiconductor optical amplifier having a first port and a second port, the first port optically connected to the optical circulator, the second port optically connected to a Faraday mirror; and
the Faraday mirror.

7. The improved optical amplifier module according to claim 6 wherein the Faraday mirror is configured to rotate polarizations of optical signals directed thereto by the dual-polarization semiconductor optical amplifier by substantially 90 degrees before reflecting the rotated polarization signals back to the dual-polarization semiconductor optical amplifier.

8. A method of operating a semiconductor optical amplifier module having an input port for receiving dual-polarization optical signals and an output port for outputting amplified, dual-polarization signals, the METHOD CHARACTERIZED IN THAT:
the dual-polarization optical signals are directed though a semiconductor optical amplifier at least twice, at least once in a first direction, and at least once in a second direction, wherein the second direction is opposite to the first direction.

9. The method of claim 8 FURTHER CHARACTERIZED IN THAT:
the dual-polarization optical signals are reflected by a Faraday mirror after being directed through the semiconductor optical amplifier the first time, but before being directed through the semiconductor optical amplifier the second time.

10. The method of claim 9 FURTHER CHARACTERIZED IN THAT:
the Faraday mirror rotates individual polarizations of the dual-polarization optical signals by substantially 90 degrees upon reflection thereby.

11. The method of claim 8 FURTHER CHARACTERIZED IN THAT:
the dual-polarization optical signals include an H polarization and a V polarization, the semiconductor optical amplifier includes first and second individual semiconductor optical amplifiers wherein the H polarization is amplified by the first semiconductor optical amplifier while traversing it in a first direction, and then amplified by the second semiconductor optical while traversing it in a second direction, wherein the second direction is opposite to the first direction, the Y polarization is amplified by the second semiconductor optical amplifier while traversing it in a third direction, and then amplified by the first semiconductor optical while traversing it in a fourth direction, wherein the fourth direction is opposite to the third direction.
